(19) United States
(12) Patent Application Publication
(10) Pub. No.: US 2016/0013384 A1
(43) Pub. Date: Jan. 14, 2016

(54) LIGHT EMITTING UNIT AND LIGHT EMITTING MODULE

(71) Applicant: Genesis Photonics Inc., Tainan City (TW)

(72) Inventors: Shao-Ying Ting, Tainan City (TW); Kuan-Chieh Huang, Tainan City (TW); Jing-En Huang, Tainan City (TW); Yi-Ru Huang, Tainan City (TW); Sie-Jhan Wu, Tainan City (TW); Long-Lin Ke, Tainan City (TW)

(21) Appl. No.: 14/474,277

(22) Filed: Sep. 1, 2014

(30) Foreign Application Priority Data
Jul. 14, 2014 (TW) 103124163

(51) Int. Cl. H01L 33/62; H01L 33/54; H01L 33/50; H01L 25/075

(52) U.S. Cl. CPC H01L 33/62; H01L 25/0753; H01L 33/54; H01L 33/50

(57) ABSTRACT

A light emitting unit includes multiple light emitting dice, a molding compound, a substrate and a patterned metal layer. Each of the light emitting dice includes a light emitting component, a first electrode and a second electrode. The molding compound encapsulates the light emitting dice and exposes a first surface of the first electrode and a second surface of the second electrode of each of the light emitting dice. The molding compound is located between the substrate and the light emitting dice. The patterned metal layer is disposed on the first surface of the first electrode and the second surface of the second electrode of each of the light emitting dice. The light emitting dice are electrically connected to each other in a series connection, a parallel connection or a series-parallel connection by the patterned metal layer.

### CROSS-REFERENCE TO RELATED APPLICATION

This application claims the priority benefit of Taiwan application serial no. 103124163, filed on Jul. 14, 2014. The entirety of the above-mentioned patent application is hereby incorporated by reference herein and made a part of this specification.

### BACKGROUND OF THE INVENTION

1. Field of the Invention

The present application relates to a light emitting unit and a light emitting module, and particularly relates to a light emitting unit and a light emitting module using light emitting dice as a light source.

2. Description of Related Art

Currently, it is common to integrate a plurality of light emitting diode (LED) packages into a light emitting diode module in the field of light emitting diodes. Here, the light emitting diode package refers to a light emitting device after the chips are packaged. The conventional light emitting diode module is formed of a plurality of light emitting diode packages and a circuit board. In addition, the light emitting diode packages are assembled on the circuit board and electrically connected to each other through the circuit board. However, it should be noted that the control of series and/or parallel connection of the light emitting diode packages on the circuit board are already set up based on voltage and current values supplied by a power supply when designing a circuit layout of the circuit board. Thus, the series and/or parallel connection of the circuit layout on the circuit board cannot be easily modified once it is completed. It requires wire jumping, wire breaking, or re-design of the circuit layout to achieve a desired design of series and/or parallel connection, which requires additional time and cost of manufacture.

### SUMMARY OF THE INVENTION

The invention provides a light emitting unit. Light emitting dice of the light emitting unit are electrically connected to each other in a series connection, a parallel connection, or a series-parallel connection through a patterned metal layer.

The invention provides a light emitting module. A light emitting unit of the light emitting module may be electrically connected with an external circuit through a patterned metal layer. The light emitting module thus has a broader applicability.

A light emitting unit of the invention includes a plurality of light emitting dice, a molding compound, a substrate, and a patterned metal layer. Each of the light emitting dice includes a light emitting component, a first electrode, and a second electrode. The first electrode and the second electrode are disposed at the same side of the light emitting component, and a gap is set between the first electrode and the second electrode. The molding compound encapsulates the light emitting dice and exposes a first surface of the first electrode and a second surface of the second electrode of each of the light emitting dice. The molding compound is located between the substrate and the light emitting dice. The patterned metal layer is disposed on the first surface of the first electrode and the second surface of the second electrode of each of the light emitting dice, wherein the light emitting dice are electrically connected to each other in a series connection, a parallel connection, or a series-parallel connection through the patterned metal layer.

According to an embodiment of the invention, the molding compound has a lower surface, and the first surface of the first electrode and the second surface of the second electrode of each of the light emitting dice are aligned with the lower surface of the molding compound.

According to an embodiment of the invention, the molding compound includes a transparent molding compound or a molding compound mixed with a phosphor.

According to an embodiment of the invention, each of the light emitting dice is a flip chip light emitting die.

According to an embodiment of the invention, the light emitting unit is a flip chip light emitting unit.

According to an embodiment of the invention, a material of the substrate includes glass, a glass phosphorous material, ceramic, or sapphire.

A light emitting module of the invention includes a light emitting unit and an external circuit. The light emitting unit includes a plurality of light emitting dice, a molding compound, a substrate, and a patterned metal layer. Each of the light emitting dice includes a light emitting component, a first electrode, and a second electrode. The first electrode and the second electrode are disposed at the same side of the light emitting component, and a gap is set between the first electrode and the second electrode. The molding compound encapsulates the light emitting dice and exposes a first surface of the first electrode and a second surface of the second electrode of each of the light emitting dice. The molding compound is located between the substrate and the light emitting dice. The patterned metal layer is disposed on the first surface of the first electrode and the second surface of the second electrode of each of the light emitting dice, wherein the light emitting dice are electrically connected to each other in a series connection, a parallel connection, or a series-parallel connection through the patterned metal layer. The external circuit is disposed under the light emitting unit, wherein the light emitting unit is electrically connected with the external circuit through the patterned metal layer.

According to an embodiment of the invention, the external circuit includes a lead frame, a circuit substrate, or a printed circuit board.

According to an embodiment of the invention, the external circuit includes a carrier board, a first external contact point, and a second external contact point, and the light emitting unit is electrically connected with the first external contact point and the second external contact point respectively through the patterned metal layer.

According to an embodiment of the invention, the external circuit includes a carrier board and a patterned circuit layer corresponding to the patterned metal layer and disposed on the carrier board, and the light emitting unit is electrically connected with the patterned circuit layer through the patterned metal layer.

According to an embodiment of the invention, the patterned metal layer and the patterned circuit layer are disposed conformally and correspondingly.

According to an embodiment of the invention, the light emitting module further includes a heat dissipating component disposed between the light emitting unit and the external circuit.

Based on the above, in the invention, the patterned metal layer is disposed on the electrodes of the light emitting dice. In addition, the light emitting dice may be electrically connected to each other in a series connection, a parallel connection or a series-parallel connection through the patterned metal layer. Thus, compared with the conventional technology where the circuit layout is directly set on the circuit board and is thus unable to easily modify the series and/or parallel connection, the applicability of design of the light emitting unit according to the invention is broader and more flexible.

To make the above features and advantages of the invention more comprehensible, embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional schematic view illustrating a light emitting unit according to an embodiment of the invention.

FIG. 2 is a cross-sectional schematic view illustrating a light emitting module according to an embodiment of the invention.

FIG. 3 is a cross-sectional schematic view illustrating a light emitting module according to another embodiment of the invention.

### DESCRIPTION OF THE EMBODIMENTS

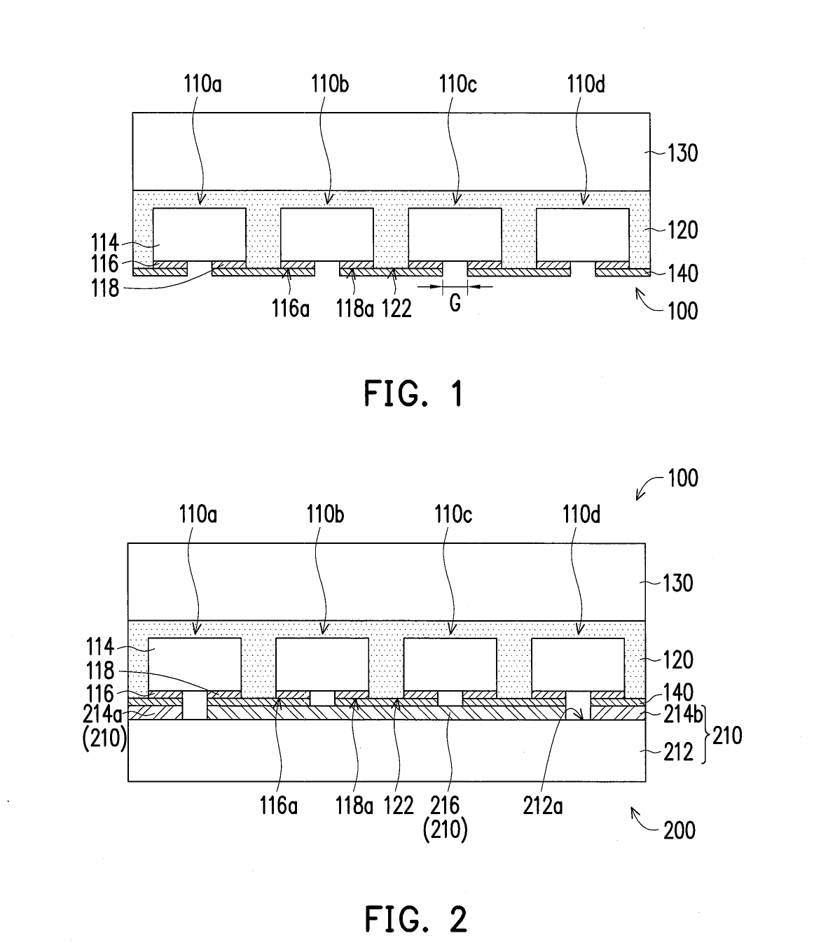

FIG. 1 is a cross-sectional schematic view illustrating a light emitting unit according to an embodiment of the invention. In this embodiment, a light emitting unit 100 includes a plurality of light emitting dice (only four light emitting dice 110a, 110b, 110c, and 110d are shown in FIG. 1 for an illustrative purpose), a molding compound 120, a substrate 130, and a patterned metal layer 140. For the ease of manufacture, the light emitting dice 110a, 110b, 110c and 110d of this embodiment may be arranged as an array. However, the invention is not limited thereto. Each of the light emitting dice 110a (or 110b, 110c, 110d) includes a light emitting component 114, a first electrode 116, and a second electrode 118. The first electrode 116 and the second electrode 118 are disposed at the same side of the light emitting component 114, and a gap G is set between the first electrode 116 and the second electrode 118. The molding compound 120 encapsulates the light emitting dice 110a, 110b, 110c, and 110d, and exposes a first surface 116a of the first electrode 116 and a second surface 118a of the second electrode 118 of each of the light emitting dice 110a (or 110b, 110c, 110d). The molding compound 120 is located between the substrate 130 and the light emitting dice 110a, 110b, 110c, and 110d. The patterned metal layer 140 is disposed on the first surface 116a of the first electrode 116 and the second surface 118a of the second electrode 118 of each of the light emitting dice 110a (or 110b, 110c, 110d). In addition, the light emitting dice 110a, 110b, 110c, and 110d are electrically connected to each other in a series connection, a parallel connection, or a series-parallel connection through the patterned metal layer 140.

More specifically, in this embodiment, the light emitting dice 110a, 110b, 110c, and 110d may be considered as bare chips, and may be in the same or different light colors, depending on requirements of the actual design. The molding compound 120 has a lower surface 122, and the first surface 116a of the first electrode 116 and the second surface 118a of the second electrode 118 of each of the light emitting dice 110a (or 110b, 110c, 110d) are aligned to the lower surface 122 of the molding compound 120. In other words, the molding compound 120 completely encapsulates the light emitting dice 110a, 110b, 110c, and 110d, and only exposes the first surfaces 116a of the first electrodes 116 and the second surfaces 118a of the second electrodes 118 of the light emitting dice 110a, 110b, 110c, and 110d, making the manufacturing process easier. However, the invention is not limited thereto. Here, the molding compound 120 may be a transparent molding compound, for example. However, the invention is not limited thereto. In other embodiments that are not shown herein, to modify a color of light provided by the light emitting unit 100, a molding compound mixed with a phosphor is chosen. In addition, the phosphor may be a yellow fluorescent powder, red fluorescent powder, green fluorescent powder, blue fluorescent powder, yttrium aluminum garnet (YAG) fluorescent powder, or a combination thereof. These embodiments are still plausible technical solutions for the invention and do not depart from the scope to which the invention intends to protect.

Moreover, a material of the substrate 130 is glass, silicon resin, acrylic resin, quartz glass, glass phosphorous material, ceramic, or sapphire, for example. In other words, the substrate 130 of this embodiment is formed of a light transmissive material and is preferably a rigid substrate, such as glass. Thus, in addition to supporting the light emitting dice 110a, 110b, 110c, and 110d and the molding compound 120, the substrate 130 also has a function of guiding light emitted by the light emitting dice 110a, 110b, 110c, and 110d and allowing the light to transmit through. Moreover, as shown in FIG. 1, the light emitting dice 110a, 110b, 110c, and 110d of this embodiment are realized as flip chip light emitting dice, and the light emitting unit 100 is realized as a flip chip light emitting unit, so as to have a smaller size.

Since the patterned metal layer 140 is disposed on the first and second electrodes 116 and 118 of the light emitting dice 110a, 110b, 110c, and 110d in this embodiment, the light emitting dice 110a, 110b, 110c, and 110d may be in a series, parallel, or series-parallel electrical connection according to a configuration regarding how the patterned metal layer 140 is disposed on the first and second electrodes 116 and 118. Namely, a series and/or parallel connection relation between the light emitting dice 110a, 110b, 110c, and 110d of this embodiment is determined based on a position where the patterned metal layer 140 is disposed, differing from the conventional art that a series and/or parallel connection relation of light emitting diode packages is determined by a circuit layout on a circuit board. In other words, the light emitting dice 110a, 110b, 110c, and 110d of this embodiment may have multiple loop designs in different configurations through the configuration of the patterned metal layer 140. Thus, the light emitting unit 100 of this embodiment offers a broader and more flexible applicability to the user.

FIG. 2 is a cross-sectional schematic view illustrating a light emitting module according to an embodiment of the invention. Referring to FIG. 2, a light emitting module 200 of this embodiment includes the light emitting unit 100 shown in FIG. 1 and an external circuit 210. In addition, the external circuit 210 is disposed under the light emitting unit 100, and the light emitting unit 100 is electrically connected with the external circuit 210 through the patterned metal layer 140. In this embodiment, the external circuit 210 is a lead frame, a circuit substrate, or a printed circuit board, for example. For example, the external circuit 210 of this embodiment is a circuit substrate, for example, and includes a carrier board 212, a first external contact point 214a and a second external contact point 214b. The first external contact point 214a and the second external contact point 214b are disposed on the carrier board 212 and expose a part of a upper surface 212a of the carrier board 212. In addition, the light emitting unit 100 is electrically connected with the first external contact point 214a and the second external contact point 214b respectively through the patterned metal layer 140. The carrier board 212 may be formed of a material having a thermally conductive property, such as ceramic. A heat dissipating component 216 having thermally conductive and heat dissipating functions may also be disposed on the part of the upper surface 212a of the carrier board 212, and heat generated by the light emitting unit 100 may be transmitted externally through the patterned metal layer 140, the first external contact point 214a and the second external contact point 214b, the heat dissipating component 216, and the carrier board 212 sequentially to rapidly dissipate the heat. Alternatively, an insulating component (not shown) may be disposed on the part of the upper surface 212a of the carrier board 212 to effectively prevent a short circuit.

Since the light emitting unit 100 of this embodiment has the patterned metal layer 140, when the light emitting unit 100 is assembled to the external circuit 210, the light emitting dice 110a, 110b, 110c, and 110d are already electrically connected to each other with the patterned metal layer 140. Therefore, the light emitting module 200 may be driven to emit light after a positive electricity and a negative electricity are respectively supplied to the first external contact point 214a and the second external contact point 214b of the external circuit 210. It is not necessary to additionally dispose a layout circuit on the external circuit 210. In other words, the external circuit 210 functions as a driving circuit here to effectively drive the light emitting module 200.

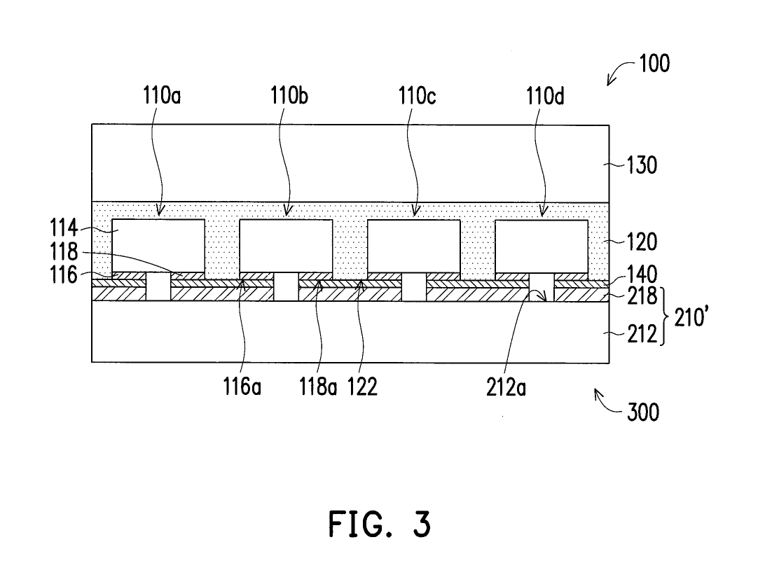

FIG. 3 is a cross-sectional schematic view illustrating a light emitting module according to another embodiment of the invention. Referring to FIGS. 2 and 3 together, a light emitting module 300 of this embodiment differs from the light emitting module 200 in the embodiment shown in FIG. 2 in that an external circuit 210′ of this embodiment includes the carrier board 212 and a patterned circuit layer 218 corresponding to the patterned metal layer 140 and disposed on the carrier board 212. In addition, the light emitting module 300 is electrically connected with the patterned circuit layer 218 through the patterned metal layer 140. Preferably, the patterned metal layer 140 and the patterned circuit layer 218 are conformally and correspondingly disposed on the carrier board 212, so as to provide a greater heat dissipating area and a greater alignment area. However, the invention is not limited thereto.

In view of the foregoing, in the invention, the patterned metal layer is disposed on the electrodes of the light emitting dice. In addition, the light emitting dice may be electrically connected to each other in a series connection, a parallel connection or a series-parallel connection through the patterned metal layer. Thus, compared with the conventional technology where the circuit layout is directly set on the circuit board and is thus unable to easily modify the series and/or parallel connection, the applicability of design of the light emitting unit according to the invention is broader and more flexible.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A light emitting unit, comprising:
a plurality of light emitting dice, each of the light emitting dice comprising a light emitting component, a first electrode, and a second electrode, wherein the first electrode and the second electrode are disposed on the same side of the light emitting component, and a gap is set between the first electrode and the second electrode;
a molding compound, encapsulating the light emitting dice and exposing a first surface of the first electrode and a second surface of the second electrode of each of the light emitting dice;
a substrate, wherein the molding compound is located between the substrate and the light emitting dice, and the substrate is a substrate plate; and
a patterned metal layer, disposed on the first surface of the first electrode and the second surface of the second electrode of each of the light emitting dice, wherein the light emitting dice are electrically connected to each other in a series connection, a parallel connection, or a series-parallel connection through the patterned metal layer.

2. The light emitting unit as claimed in claim 1, wherein the molding compound has a lower surface, and the first surface of the first electrode and the second surface of the second electrode of each of the light emitting dice are aligned with the lower surface of the molding compound.

3. The light emitting unit as claimed in claim 1, wherein the molding compound comprises a transparent molding compound or a molding compound mixed with a phosphor.

4. The light emitting unit as claimed in claim 1, wherein each of the light emitting dice is a flip chip light emitting die.

5. The light emitting unit as claimed in claim 1, wherein the light emitting unit is a flip chip light emitting unit.

6. The light emitting unit as claimed in claim 1, wherein a material of the substrate comprises glass, a glass phosphorous material, ceramic, or sapphire.

7. A light emitting module, comprising:
a light emitting unit, comprising:
a plurality of light emitting dice, each of the light emitting dice comprising a light emitting component, a first electrode, and a second electrode, wherein the first electrode and the second electrode are disposed on the same side of the light emitting component, and a gap is set between the first electrode and the second electrode;
a molding compound, encapsulating the light emitting dice and exposing a first surface of the first electrode and a second surface of the second electrode of each of the light emitting dice;
a substrate, wherein the molding compound is located between the substrate and the light emitting dice, and the substrate is a substrate plate; and
a patterned metal layer, disposed on the first surface of the first electrode and the second surface of the second electrode of each of the light emitting dice, wherein the light emitting dice are electrically connected to each other in a series connection, a parallel connection, or a series-parallel connection through the patterned metal layer; and
an external circuit, disposed under the light emitting unit, wherein the light emitting unit is electrically connected with the external circuit through the patterned metal layer.

8. The light emitting module as claimed in claim 7, wherein the external circuit comprises a lead frame, a circuit substrate, or a printed circuit board.

9. The light emitting module as claimed in claim 7, wherein the external circuit comprises a carrier board, a first external contact point, and a second external contact point, and the light emitting unit is electrically connected with the first external contact point and the second external contact point respectively through the patterned metal layer.

10. The light emitting module as claimed in claim 7, wherein the external circuit comprises a carrier board and a patterned circuit layer corresponding to the patterned metal layer and disposed on the carrier board, and the light emitting unit is electrically connected with the patterned circuit layer through the patterned metal layer.

11. The light emitting module as claimed in claim 10, wherein the patterned metal layer and the patterned circuit layer are disposed conformally and correspondingly.

12. The light emitting module as claimed in claim 10, further comprising:
a heat dissipating component, disposed between the light emitting unit and the external circuit.

13. The light emitting unit as claimed in claim 1, wherein the substrate is a rigid substrate.

14. The light emitting module as claimed in claim 7, wherein the substrate is a rigid substrate.
